(19) United States
(12) Patent Application Publication
(10) Pub. No.: US 2024/0150651 A1
(43) Pub. Date: May 9, 2024

(54) QUANTUM DOT, METHOD FOR PREPARING THE QUANTUM DOT, AND DISPLAY DEVICE COMPRISING THE QUANTUM DOT

(71) Applicant: Samsung Display Co., Ltd., Yongin-si (KR)

(72) Inventors: SEUNG-WON PARK, Yongin-si (KR); SUNGJAE KIM, Yongin-si (KR); Youngsik KIM, Yongin-si (KR); Bitna YOON, Yongin-si (KR); DONGHEE LEE, Yongin-si (KR); JUNEHYUK JUNG, Yongin-si (KR)

(73) Assignee: Samsung Display Co., Ltd., Yongin-si (KR)

(21) Appl. No.: 18/365,337

(22) Filed: Aug. 4, 2023

(30) Foreign Application Priority Data
Nov. 8, 2022 (KR) 10-2022-0148131

(51) Int. Cl. C09K 11/88; C09K 11/08; H10K 59/35; H10K 59/38

(52) U.S. Cl. CPC C09K 11/883; C09K 11/0883; H10K 59/352; H10K 59/38; B82Y 20/00

(57) ABSTRACT

Embodiments provide a quantum dot that includes a core including zinc (Zn), tin (Sn) and phosphorus (P), and a shell surrounding the core, wherein a molar ratio of a number of moles of zinc to a number of moles of tin is in a range of about 0.1 to about 2. The quantum dots have high luminous efficiency and color purity.

### CROSS-REFERENCE TO RELATED APPLICATION(S)

This application claims priority to and benefits of Korean Patent Application No. 10-2022-0148131 under 35 U.S.C. § 119, filed on Nov. 8, 2022, in the Korean Intellectual Property Office, the entire contents of which are incorporated herein by reference.

### BACKGROUND

### 1. Technical Field

The disclosure relates to a quantum dot, a method for preparing the quantum dot, and a display device including the quantum dot.

### 2. Description of the Related Art

Various display devices used in multimedia apparatuses such as televisions, mobile phones, tablet computers, navigation units, and game consoles have been developed. In such a display device, a so-called self-luminous display element may be used that achieves display by causing a light-emitting material containing an organic compound to emit light.

Development of a light-emitting element using quantum dots as a light-emitting material is in progress in order to improve the color reproducibility of a display device, and there is a demand for improving the service life and luminous efficiency of a light-emitting element using quantum dots.

It is to be understood that this background of the technology section is, in part, intended to provide useful background for understanding the technology. However, this background of the technology section may also include ideas, concepts, or recognitions that were not part of what was known or appreciated by those skilled in the pertinent art prior to a corresponding effective filing date of the subject matter disclosed herein.

### SUMMARY

Embodiments provide a quantum dot with low production costs by including a core containing zinc, tin, and phosphorus, and a shell.

Embodiments also provide a quantum dot that has high absorbance of blue light since a molar ratio of zinc to tin in the core may be in a range of about 0.1 to about 2.

Embodiments also provide a display device having an improved luminous efficiency and an improved color reproducibility.

An embodiment provides a quantum dot which may include: a core including zinc (Zn), tin (Sn), and phosphorus (P); and a shell surrounding the core, wherein a molar ratio of a number of moles of zinc to the number of moles of tin may be in a range of about 0.1 to about 2.

In an embodiment, the core may further include at least one of: a Group II element except zinc; a Group IV element except tin; or a Group V element except phosphorus.

In an embodiment, a molar ratio of a number of moles of the Group II element to a number of moles of zinc, a molar ratio of a number of moles of the Group IV element to a number of moles of tin, and a molar ratio of a number of moles of the Group V element to a number of moles of phosphorus may each independently be in a range of about 0.1 to about 1.

In an embodiment, the core may not include a Group I element, a Group III element, or a Group VI element.

In an embodiment, the shell may include at least one of a Group II-VI compound, a Group III-V compound, a Group III-VI compound, a Group I-III-VI compound, a Group II-V compound, a Group II-IV-V compound, or a Group IV-V compound.

In an embodiment, the shell may include at least one of ZnSe, ZnS, ZnSeS, GaS, or InS.

In an embodiment, the shell may include a first shell surrounding the core, and a second shell surrounding the first shell, and the first shell and the second shell each independently may include at least one of ZnSe, ZnS, or ZnSeS.

In an embodiment, the quantum dot may have a weight absorption coefficient equal to or greater than about 350 mL·g⁻¹·cm⁻¹ with respect to a wavelength of about 450 nm.

In an embodiment, the quantum dot may absorb light having a central wavelength in a range of about 440 nm to about 465 nm, and the quantum dot may emit light having a central wavelength in a range of about 480 nm to about 560 nm.

In an embodiment, the quantum dot may have a radius in a range of about 0.5 nm to about 5 nm.

An embodiment provides a display device which may include: a light-emitting element including a first electrode, a light-emitting layer disposed on the first electrode, and a second electrode disposed on the light-emitting layer; and
a light control layer including a first light control part that transmits the source light, and a second light control part that converts the source light into first light, and a first quantum dot, wherein
the light-emitting element may output a source light, the light control layer may be disposed on the light-emitting element,
the first quantum dot may include a core containing zinc, tin, and phosphorus, and a shell surrounding the core, and a molar ratio of a number of moles of zinc to the number of moles of tin may be in a range of about 0.1 to about 2.

In an embodiment, the first quantum dot may absorb the source light and may emit the first light, the source light may have a central wavelength in a range of about 440 nm to about 465 nm, and the first light may have a central wavelength in a range of about 480 nm to about 560 nm.

In an embodiment, the light control layer may further include a third light control part that converts the source light into a second light, the third light control part may include a second quantum dot, the second quantum dot may absorb the source light and may emit the second light, and the second light may have a central wavelength in a range of about 600 nm to about 640 nm.

An embodiment provides a method for preparing a quantum dot which may include: forming a core containing elemental zinc, elemental tin, and elemental phosphorus by adding a first compound containing elemental phosphorus, a zinc precursor, a tin precursor, and a first solvent; and forming a shell by reacting the core with a second compound, wherein a molar ratio of a number of moles of zinc to a number of moles of tin in the core may be in a range of about 0.1 to about 2.

In an embodiment, the forming of the core may include: providing a first mixture including the first compound, the zinc precursor, the tin precursor, and the first solvent; and heating the first mixture at a temperature in a range of about 100° C. to about 300° C.

In an embodiment, the providing of the first mixture may include: providing a first preliminary mixture including the zinc precursor, the tin precursor, and the first solvent; and adding the first compound to the first preliminary mixture.

In an embodiment, the forming of the core may include: providing a second mixture including the zinc precursor and a second solvent; providing a first solution by adding the first compound to the second mixture; providing a second solution containing the tin precursor and a third solvent; and mixing the first solution and the second solution, and the mixing of the first solution and the second solution may include an exchange reaction between zinc cations of the first solution and tin cations of the second solution.

In an embodiment, the providing of the first solution may include: providing a third mixture by adding the first compound to the second mixture; and forming a zinc phosphide compound by heating the third mixture.

In an embodiment, the forming of the core may include: providing a fourth mixture containing the tin precursor and a fourth solvent; providing a third solution by adding the first compound to the fourth mixture; providing a fourth solution containing the zinc precursor and a fifth solvent, and mixing the third solution and the fourth solution, and the mixing of the third solution and the fourth solution may include an exchange reaction between tin cations of the third solution and zinc cations of the fourth solution.

In an embodiment, the providing of the third solution may include: providing a fifth mixture by adding the first compound to the fourth mixture; and forming a tin phosphide compound by heating the fifth mixture.

It is to be understood that the embodiments above are described in a generic and explanatory sense only and not for the purpose of limitation, and the disclosure is not limited to the embodiments described above.

### BRIEF DESCRIPTION OF THE DRAWINGS

The accompanying drawings are included to provide a further understanding of embodiments, and are incorporated in and constitute a part of this specification. The drawings illustrate embodiments of the disclosure and principles thereof. The above and other aspects and features of the disclosure will become more apparent by describing in detail embodiments thereof with reference to the accompanying drawings, in which:

FIG. 1 is a schematic perspective view of a display device according to an embodiment;

FIG. 2 is a schematic cross-sectional view, of a display device according to an embodiment, taken along line I-I′ of FIG. 1;

FIG. 3 is an enlarged schematic plan view illustrating a portion of a display device according to an embodiment;

FIGS. 4A and 4B are each schematic a cross-sectional view of a display device according to an embodiment;

FIG. 5 is a schematic cross-sectional view of a structure of a quantum dot according to an embodiment;

FIGS. 6A and 6B are each a flowchart of a method for preparing a quantum dot according to an embodiment; and

FIGS. 7A and 7B are each a flowchart of a part of a method for preparing a quantum dot according to an embodiment.

### DETAILED DESCRIPTION OF THE EMBODIMENTS

The disclosure will now be described more fully hereinafter with reference to the accompanying drawings, in which embodiments are shown. This disclosure may, however, be embodied in different forms and should not be construed as limited to the embodiments set forth herein. Rather, these embodiments are provided so that this disclosure will be thorough and complete, and will fully convey the scope of the disclosure to those skilled in the art.

In the drawings, the sizes, thicknesses, ratios, and dimensions of the elements may be exaggerated for ease of description and for clarity. Like reference numbers and/or like reference characters refer to like elements throughout.

In the description, it will be understood that when an element (or region, layer, part, etc.) is referred to as being “on”, “connected to”, or “coupled to” another element, it can be directly on, connected to, or coupled to the other element, or one or more intervening elements may be present therebetween. In a similar sense, when an element (or region, layer, part, etc.) is described as “covering” another element, it can directly cover the other element, or one or more intervening elements may be present therebetween.

In the description, when an element is “directly on,” “directly connected to,” or “directly coupled to” another element, there are no intervening elements present. For example, “directly on” may mean that two layers or two elements are disposed without an additional element such as an adhesion element therebetween.

It will be understood that the terms “connected to” or “coupled to” may refer to a physical, electrical and/or fluid connection or coupling, with or without intervening elements.

As used herein, the expressions used in the singular such as “a,” “an,” and “the,” are intended to include the plural forms as well, unless the context clearly indicates otherwise.

As used herein, the term “and/or” includes any and all combinations of one or more of the associated listed items. For example, “A and/or B” may be understood to mean “A, B, or A and B.” The terms “and” and “or” may be used in the conjunctive or disjunctive sense and may be understood to be equivalent to “and/or”.

In the specification and the claims, the term “at least one of” is intended to include the meaning of “at least one selected from the group of” for the purpose of its meaning and interpretation. For example, “at least one of A and B” may be understood to mean “A, B, or A and B.” When preceding a list of elements, the term, “at least one of,” modifies the entire list of elements and does not modify the individual elements of the list.

It will be understood that, although the terms first, second, etc. may be used herein to describe various elements, these elements should not be limited by these terms. These terms are only used to distinguish one element from another element. Thus, a first element could be termed a second element without departing from the teachings of the disclosure. Similarly, a second element could be termed a first element, without departing from the scope of the disclosure.

The spatially relative terms “below”, “beneath”, “lower”, “above”, “upper”, or the like, may be used herein for ease of description to describe the relations between one element or component and another element or component as illustrated in the drawings. It will be understood that the spatially relative terms are intended to encompass different orientations of the device in use or operation, in addition to the orientation depicted in the drawings. For example, in the case where a device illustrated in the drawing is turned over, the device positioned “below” or “beneath” another device may be placed “above” another device. Accordingly, the illustrative term “below” may include both the lower and upper positions. The device may also be oriented in other directions and thus the spatially relative terms may be interpreted differently depending on the orientations.

The terms “about” or “approximately” as used herein is inclusive of the stated value and means within an acceptable range of deviation for the recited value as determined by one of ordinary skill in the art, considering the measurement in question and the error associated with measurement of the recited quantity (i.e., the limitations of the measurement system). For example, “about” may mean within one or more standard deviations, or within ±20%, ±10%, or ±5% of the stated value.

It should be understood that the terms “comprises,” “comprising,” “includes,” “including,” “have,” “having,” “contains,” “containing,” and the like are intended to specify the presence of stated features, integers, steps, operations, elements, components, or combinations thereof in the disclosure, but do not preclude the presence or addition of one or more other features, integers, steps, operations, elements, components, or combinations thereof.

Unless otherwise defined or implied herein, all terms (including technical and scientific terms) used have the same meaning as commonly understood by those skilled in the art to which this disclosure pertains. It will be further understood that terms, such as those defined in commonly used dictionaries, should be interpreted as having a meaning that is consistent with their meaning in the context of the relevant art and should not be interpreted in an ideal or excessively formal sense unless clearly defined in the specification.

In this specification, “directly disposed” may mean disposing between two layers or two members without using an additional member such as an adhesive member. For example, “directly disposed” may mean disposing without additional members such as adhesive members between two layers or two members.

In this specification, “Group” refers to a Group of the IUPAC Periodic Table.

In this specification, “Group II” may include a Group IIA element and a Group IIB element. For example, a Group II element may be magnesium (Mg) or zinc (Zn), but is not limited thereto.

In this specification, “Group III” may include a Group IIIA element and a Group IIIB element. For example, the Group III element may be aluminum (Al), indium (In), gallium (Ga), or titanium (Ti), but is not limited thereto.

In this specification, “Group IV” may include a Group IVA element and a Group IVB element. For example, the Group IV element may be tin (Sn), silicon (Si), or germanium (Ge), but is not limited thereto.

In this specification, “Group V” may include a Group VA element and a Group VB element. For example, the Group V element may be phosphorus (P), arsenic (As), or antimony (Sb), but is not limited thereto.

In this specification, “Group VI” may include a Group VIA element and a Group VIB element. For example, the Group VI element may be oxygen (O), sulfur (S), selenium (Se) or tellurium (Te), but is not limited thereto.

In this specification, “Group VII” may include a Group VIIA element. For example, the Group VII element may be manganese (Mn), but is not limited thereto.

Hereinafter, a quantum dot, a light-emitting element, and a display device including the same according to an embodiment will be described with reference to the drawings.

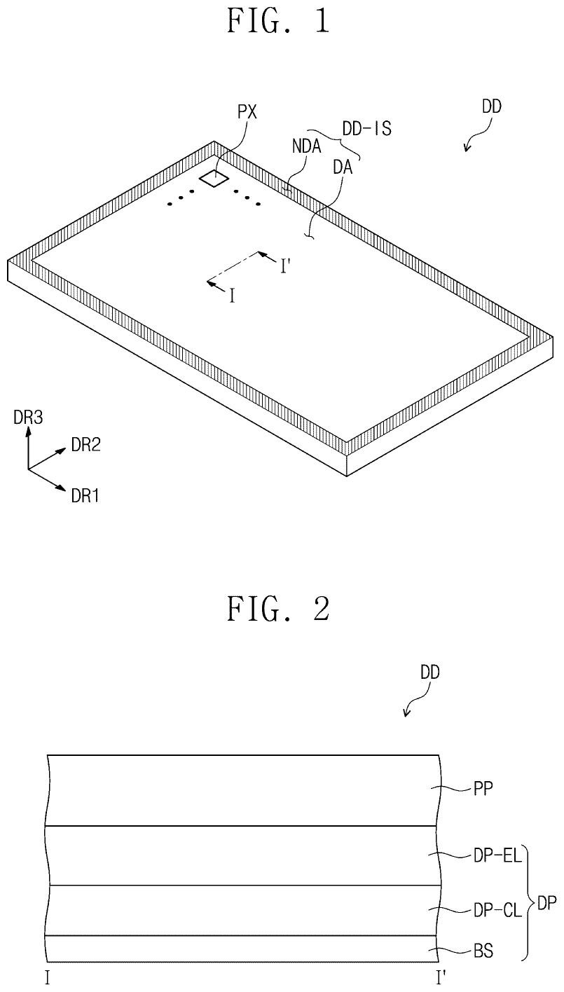

FIG. 1 is a schematic perspective view of a display device DD according to an embodiment. FIG. 1 illustrates a display device DD having a flat display surface DD-IS, but embodiments are not limited thereto. The display device DD may also include a curved display surface or a three-dimensional display surface. A three-dimensional display surface may include multiple display regions indicating different directions.

The display surface DD-IS may include a display region DA and a non-display region NDA. Pixels PX may be disposed in the display region DA, but the pixels PX may not be disposed in the non-display region NDA. The non-display region NDA may be defined along an edge of the display surface DD-IS. The non-display region NDA may surround the display region DA. However, embodiments are not limited thereto, and the non-display region NDA may be omitted or disposed on only one side of the display region DA.

A thickness direction of the display device DD may be parallel to a third direction DR3 that is a normal direction of a plane defined by the first direction DR1 and the second direction DR2. The directions indicated by the first to third directions DR1, DR2, and DR3 illustrated in this specification may have a relative concept and may thus be changed to other directions.

In the specification, an upper surface (or a front surface) and a lower surface (or a rear surface) of each member constituting the display device DD may be defined based on the third direction DR3. For example, among two surfaces, of one member, facing each other in the third direction DR3, a surface relatively more adjacent to the display surface DD-IS may be defined as a front surface (or upper surface), and a surface relatively farther spaced apart from the display surface DD-IS may be defined as a rear surface (or lower surface). In the specification, an upper portion and a lower portion may be defined based on the third direction DR3, a portion closer to the display surface DD-IS may be defined as an upper portion, and a portion farther away from the display surface DD-IS may be defined as a lower portion.

FIG. 2 is a schematic cross-sectional view of a display device according to an embodiment, taken along line I-F of FIG. 1.

Referring to FIG. 2, the display device DD may include a display panel DP and an optical structure layer PP disposed on the display panel DP.

The optical structure layer PP may be disposed on the display panel DP and may control light that is reflected at the display panel DP from an external light. The optical structure layer PP may include, for example, a polarizing layer or a color filter layer.

In the display device DD according to an embodiment, the display panel DP may be a light-emitting display panel. For example, the display panel DP may be a quantum dot light-emitting display panel including a quantum dot light-emitting element. However, embodiments are not limited thereto.

The display panel DP may include a display element layer DP-EL. The display element layer DP-EL may include the light-emitting element. The display panel DP may include a base substrate BS, a circuit layer DP-CL disposed on the base substrate BS, and a display element layer DP-EL disposed on the circuit layer DP-CL.

The base substrate BS may provide a base surface on which the display element layer DP-EL is disposed. The base substrate BS may be a glass substrate, a metal substrate, a plastic substrate, or the like. However, embodiments are not limited thereto, and the base substrate BS may include an inorganic layer, an organic layer, or a composite material layer. The base substrate BS may be a flexible substrate which may be readily bent or folded.

In an embodiment, the circuit layer DP-CL may be disposed on the base substrate BS, and the circuit layer DP-CL may include transistors (not shown). Each of the transistors (not shown) may include a control electrode, an input electrode, and an output electrode. For example, the circuit layer DP-CL may include a switching transistor and a driving transistor for driving the light-emitting element of the display element layer DP-EL.

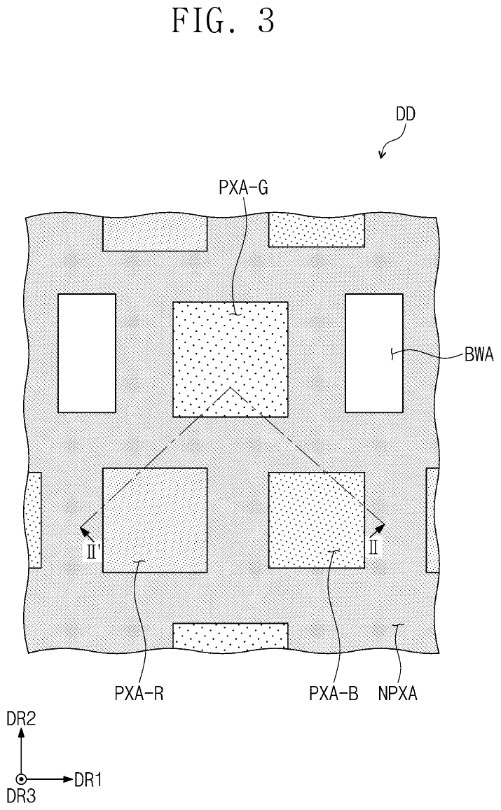

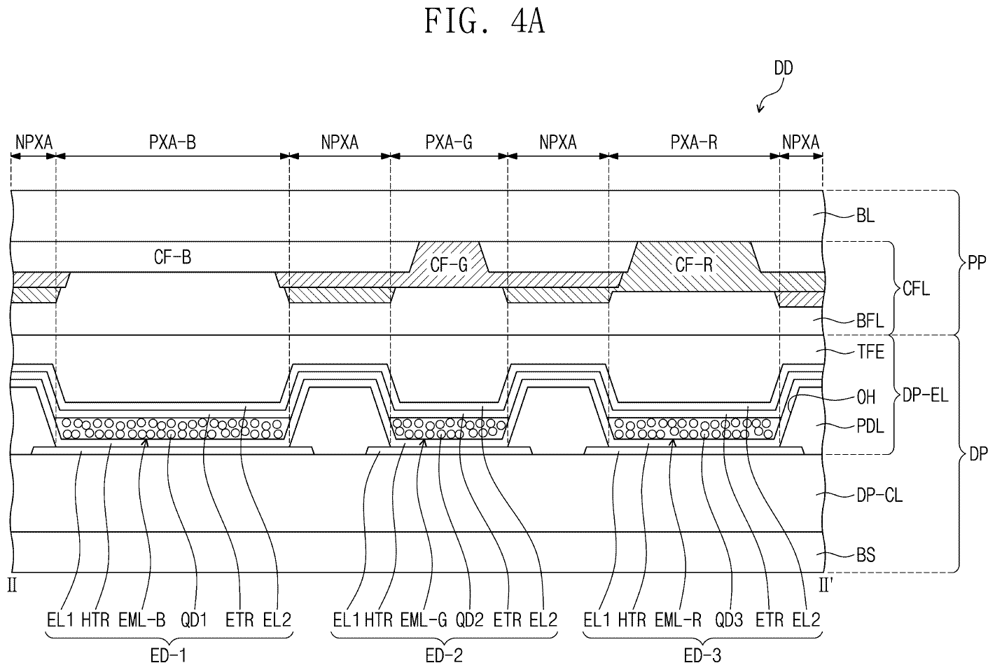

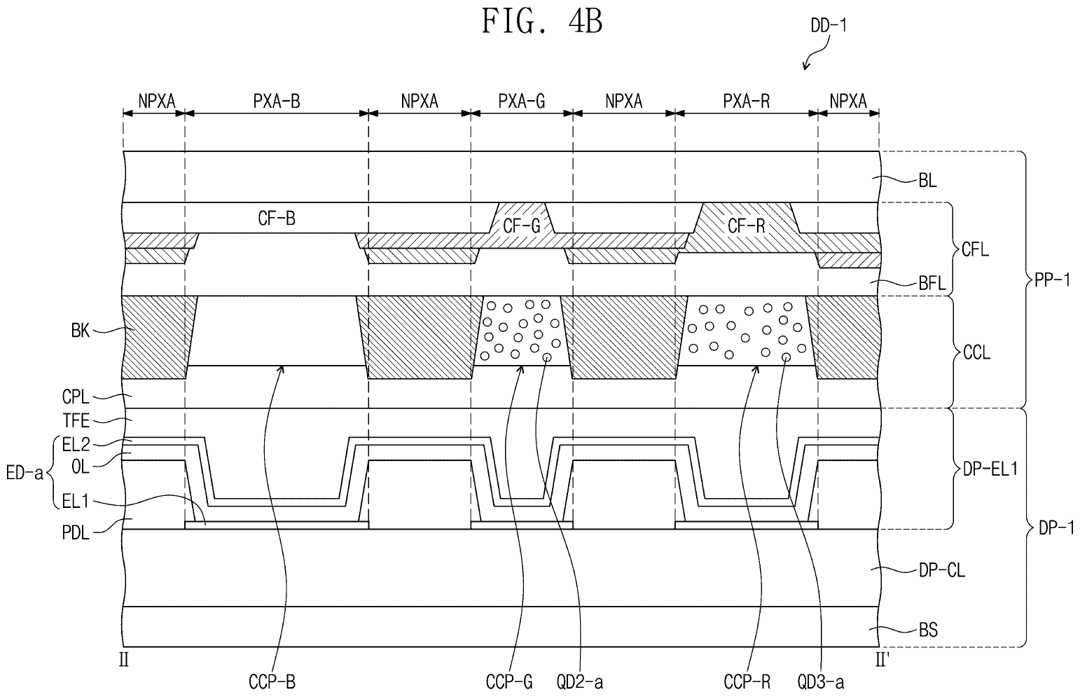

FIG. 3 is an enlarged schematic plan view of a portion of a display device DD according to an embodiment. FIG. 4A is a schematic cross-sectional view of a display device DD according to an embodiment. FIG. 4B is a schematic cross-sectional view of a display device DD-1 according to another embodiment. FIGS. 4A and 4B illustrate a portion of the display region DA of the display panel according to an embodiment. FIGS. 4A and 4B each illustrate a portion taken along line II-IF of FIG. 3.

Referring to FIG. 3, the display device DD according to an embodiment may include a flat surface that includes three pixel regions PXA-R, PXA-B, and PXA-G and bank well regions BWA adjacent thereto. In an embodiment, the three pixel regions PXA-R, PXA-B, and PXA-G illustrated in FIG. 3 may be repeatedly disposed throughout the display region DA (see FIG. 1).

A peripheral region NPXA may be disposed around the first to third pixel regions PXA-R, PXA-B, and PXA-G. The peripheral region NPXA sets boundaries between the first to third pixel regions PXA-R, PXA-B, and PXA-G. The peripheral region NPXA may surround the first to third pixel regions PXA-R, PXA-B, and PXA-G. A structure, such as a pixel defining film (see FIG. 4A), which prevents color mixing between the first to third pixel regions PXA-R, PXA-B, and PXA-G, may be disposed in the peripheral region NPXA.

FIG. 3 illustrates the first to third pixel regions PXA-R, PXA-B, and PXA-G as having a same planar shape and having different planar areas, but embodiments are not limited thereto. At least two pixel regions among the first to third pixel regions PXA-R, PXA-B, and PXA-G may have a same area. The areas of the first to third pixel regions PXA-R, PXA-B, and PXA-G may be set depending on the colors of emitted light.

FIG. 3 illustrates the first to third pixel regions PXA-R, PXA-B, and PXA-G as having a rectangular shape, but embodiments are not limited thereto. In a plan view, the first to third pixel regions PXA-R, PXA-B, and PXA-G may have a polygonal shape (for example, a substantially polygonal shape) having a different shape such as a rhombus or a pentagon. In an embodiment, the first to third pixel regions PXA-R, PXA-B, and PXA-G may have, in a plan view, a rectangular shape (for example, a substantially rectangular shape) having rounded corners.

FIG. 3 illustrates that the second pixel region PXA-G is disposed in a first row, and the first pixel region PXA-B and the third pixel region PXA-R are disposed in a second row, but embodiments are not limited thereto. The arrangement of the first to third pixel regions PXA-R, PXA-B, and PXA-G may be variously changed. For example, the first to third pixel regions PXA-R, PXA-B, and PXA-G may be arranged in a same row.

The bank well regions BWA may be defined in the display region DA (see FIG. 1). The bank well regions BWA may be regions in which bank wells (not shown) are formed to prevent defects due to erroneous deposition in the process of patterning the light control patterns CCP-R, CCP-B, and CCP-G (see FIG. 4B) included in the light control layer CCL (see FIG. 4B). For example, the bank well region BWA may be a region in which a bank well formed by removing a portion of the bank (not shown) is defined.

FIG. 3 illustrates that two bank well regions BWA may be adjacent to the second pixel region PXA-G, but embodiments are not limited thereto, and the shape and arrangement of the bank well regions BWA may be variously changed.

In the display device DD according to an embodiment illustrated in FIG. 3, three light-emitting regions PXA-B, PXA-G, and PXA-B respectively emitting blue light, green light, and red light are illustrated. For example, the display device DD according to an embodiment may include a blue light-emitting region PXA-B, a green light-emitting region PXA-G, and a red light-emitting region PXA-R that are distinguished from each other.

Referring to FIGS. 4A and 4B, the display devices DD and DD-1 according to an embodiment may respectively include display panels DP and DP-1 having light-emitting elements ED-1, ED-2, ED-3, and ED-a, and optical structure layers PP and PP-1 respectively disposed on display panels DP and DP-1.

The display panels DP and DP-1 may each include a base substrate BS, and a circuit layer DP-CL and a display element layer DP-EL and DP-EL1 which are provided on the base substrate BS. The display element layer DP-EL and DP-EL1 may each include pixel defining films PDL, the light-emitting elements ED-1, ED-2, ED-3, and ED-a disposed between or on the pixel defining films PDL, and an encapsulation layer TFE disposed on the light-emitting elements ED-1, ED-2, ED-3, and ED-a.

The display element layers DP-EL and DP-EL1 may each include the pixel defining films PDL. Each of the light-emitting regions PXA-R, PXA-G, and PXA-B may be regions separated by the pixel defining films PDL. The non-light-emitting regions NPXA may be provided between the adjacent light-emitting regions PXA-B, PXA-G, and PXA-R and may correspond to the pixel defining films PDL. In the specification, the light-emitting regions PXA-B, PXA-G, and PXA-R may each correspond to a pixel. Referring to FIG. 4A, the pixel defining films PDL may separate the light-emitting elements ED-1, ED-2, and ED-3. Light-emitting layers EML-R, EML-G, and EML-B of the light-emitting elements ED-1, ED-2, and ED-3 may be disposed and separated in the openings OH defined in the pixel defining film PDL.

The pixel defining films PDL may be formed of a polymer resin. For example, the pixel defining films PDL may include a polyacrylate-based resin or a polyimide-based resin. The pixel defining films PDL may further include an inorganic material, in addition to the polymer resin. The pixel defining films PDL may include a light-absorbing material or may include a black pigment or black dye. The pixel defining films PDL including the black pigment or black dye may form a black pixel defining film. Carbon black or the like may be used as the black pigment or black dye when the pixel defining film PDL is formed, but embodiments are not limited thereto.

The pixel defining films PDL may be formed of an inorganic material. For example, the pixel defining films PDL may include silicon nitride (SiNₓ), silicon oxide (SiOₓ), silicon oxynitride (SiOₓN_{y}), or the like. The pixel defining films PDL may define the light-emitting regions PXA-B, PXA-G, and PXA-B. The light-emitting regions PXA-B, PXA-G, and PXA-R and the non-light-emitting region NPXA may be separated by the pixel defining films PDL.

Referring to FIG. 4A, the display element layer DP-EL may include light-emitting elements ED-1, ED-2, and ED-3 disposed between the pixel defining films PDL. The display device DD may include the light-emitting elements ED-1, ED-2, and ED-3, and the light-emitting elements ED-1, ED-2, and ED-3 may respectively include light-emitting layers EML-B, EML-G, and EML-R. The light-emitting elements ED-1, ED-2, and ED-3 according to an embodiment may include a first electrode EL1, a second electrode EL2 facing the first electrode EL1, and functional layers disposed between the first electrode EL1 and the second electrode EL2 and including the light-emitting layers EML-B, EML-G, and EML-R.

The functional layers may include a hole transport region HTR disposed between the first electrode EL1 and the light-emitting layer EML, and an electron transport region ETR disposed between the light-emitting layer EML and the second electrode EL2. Although not illustrated in the drawings, in an embodiment, a capping layer may be further disposed on the second electrode EL2.

The hole transport region HTR and the electron transport region ETR may each include sub-functional layers. For example, the hole transport region HTR may include a hole injection layer and a hole transport layer as sub-functional layers, and the electron transport region ETR may include an electron injection layer and an electron transport layer as sub functional layers. However, embodiments are not limited thereto, and the hole transport region HTR may further include an electron blocking layer or the like as a sub-functional layer, and the electron transport region ETR may further include a hole blocking layer or the like as a sub-functional layer.

The first electrode EL1 may have conductivity. The first electrode EL1 may be formed of a metal alloy or a conductive compound. The first electrode EL1 may be an anode. The first electrode EL1 may be a pixel electrode. The first electrode EL1 may be a reflective electrode. However, embodiments are not limited thereto, and the first electrode EL1 may be a transmissive electrode or a transflective electrode. When the first electrode EL1 is a transflective electrode or a reflective electrode, the first electrode EL1 may include Ag, Mg, Cu, Al, Pt, Pd, Au, Ni, Nd, Ir, Cr, Li, Ca, LiF/Ca, LiF/Al, Mo, Ti, Yb, W, a compound thereof, or a mixture thereof (e.g., a mixture of Ag and Mg). In another embodiment, the first electrode EL1 may have a multi-layered structure including a reflective film or a semi-transmissive film formed of the materials described above, and a transparent conductive film formed of indium tin oxide (ITO), indium zinc oxide (IZO), zinc oxide (ZnO), or indium tin zinc oxide (ITZO). For example, the first electrode EL1 may be a multilayer metal film or may have a structure in which ITO/Ag/ITO metal films are stacked.

The hole transport region HTR may be provided on the first electrode ELL The hole transport region HTR may include a hole injection layer (not shown), a hole transport layer (not shown), etc. The hole transport region HTR may be a layer consisting of a single material, a layer including different materials, or a structure including multiple layers including different materials.

The hole transport region HTR may be formed through various methods such as a vacuum evaporation method, a spin coating method, a cast method, a Langmuir-Blodgett (LB) method, an inkjet printing method, a laser printing method, or a laser induced thermal imaging (LITI) method.

For example, the hole transport region HTR may include a carbazole-based derivative such as N-phenylcarbazole and polyvinylcarbazole, a fluorene-based derivative, N,N′-bis(3-methylphenyl)-N,N′-diphenyl-[1,1′-biphenyl]-4,4′-diamine (TPD), a triphenylamine-based derivative such as 4,4′,4″-tris(N-carbazolyl)triphenylamine (TCTA), N,N′-di(naphthalene-1-yl)-N,N′-diphenyl-benzidine (NPD), 4,4 ‘-cyclohexylidene bis[N,N-bis(4-methylphenyl)benzenamine] (TAPC), 4,4’-bis[N,N′-(3-tolyl)amino]-3,3′-dimethylbiphenyl (HMTPD), 1,3-bis(N-carbazolyl)benzene (mCP), and the like.

The hole transport region HTR may have a thickness in a range of about 5 nm to about 1,500 nm. For example, the hole transport region HTR may have a thickness in a range of about 10 nm to about 500 nm. When the thickness of the hole transport region HTR satisfies any of the above-described ranges, satisfactory hole transport characteristics may be obtained without a substantial increase in driving voltage.

The light-emitting layers EML-B, EML-G, and EML-R may be provided on the hole transport region HTR. The light-emitting layer EML may include a host and a dopant. In an embodiment, the light-emitting layer EML may include quantum dots QD as a dopant material. In an embodiment, the light-emitting layer EML may further include a host material.

The light-emitting layers EML-B, EML-G, and EML-R may respectively include quantum dots QD1, QD2, and QD3. In an embodiment, the light-emitting layers EML-B, EML-G, and EML-R may emit fluorescence. For example, quantum dots QD1, QD2, and QD3 may be used as a fluorescent dopant material.

The quantum dots QD1, QD2, and QD3 respectively included in the light-emitting layers EML-B, EML-G, and EML-R may be stacked to form a layer. FIG. 4A illustrates that quantum dots QD1, QD2, and QD3 each having a circular shape in a cross-sectional view are arranged in two layers, but embodiments are not limited thereto. For example, an arrangement of the quantum dots QD1, QD2, and QD3 may change according to thicknesses of the light-emitting layers EML-B, EML-G, and EML-R, shapes of the quantum dots QD1, QD2, and QD3 respectively included in the light-emitting layers EML-B, EML-G, and EML-R, and an average diameter of the quantum dots QD1, QD2, and QD3, etc. For example, in the light-emitting layers EML-B, EML-G, and EML-R, the quantum dots QD1, QD2, and QD3 may be arranged adjacent to each other to form one layer or may be arranged to form multiple layers such as two or three layers.

The first light-emitting layer EML-B of the first light-emitting element ED-1 may include the first quantum dot QD1. The first quantum dot QD1 may emit blue light. The second light-emitting layer EML-G of the second light-emitting element ED-2 may include the second quantum dots QD2. The second quantum dot QD2 may emit green light. The third light-emitting layer EML-R of the third light-emitting element ED-3 may include the third quantum dot QD3. The third quantum dot QD3 may emit red light.

Each of the quantum dots QD1, QD2, and QD3 may include a core and a shell surrounding the core. Accordingly, each of the quantum dots QD1, QD2, and QD3 may have a core-shell structure. In an embodiment, the first to third quantum dots QD1, QD2, and QD3 respectively included in the light-emitting elements ED-1, ED-2, and ED-3 may be formed of different core materials. In another embodiment, the first to third quantum dots QD1, QD2, and QD3 may be formed of a same core material, or two quantum dots selected from the first to third quantum dots QD1, QD2, and QD3 may be formed of a same core material and the other quantum dot may be formed of another core material.

In an embodiment, the first to third quantum dots QD1, QD2, and QD3 may have different diameters. For example, the first quantum dot QD1 used in the first light-emitting element ED-1 emitting light in a relatively short wavelength region may have a smaller average diameter than the second quantum dot QD2 of the second light-emitting element ED-2 and the third quantum dot QD3 of the third light-emitting element ED-3 each emitting light in a longer wavelength region. In the specification, an average diameter may be an arithmetic average of the diameters of the quantum dots. The diameter of quantum dot particles may be an average value of the widths of the quantum dots in a cross section.

The relationship between the average diameters of the first to third quantum dots QD1, QD2, and QD3 is not limited to the above limitations. For example, FIG. 4A illustrates that the sizes of the first to third quantum dots QD1, QD2, and QD3 may all be similar. However, the first to third quantum dots QD1, QD2, and QD3 included in the light-emitting elements ED-1, ED-2, and ED-3 may have different sizes.

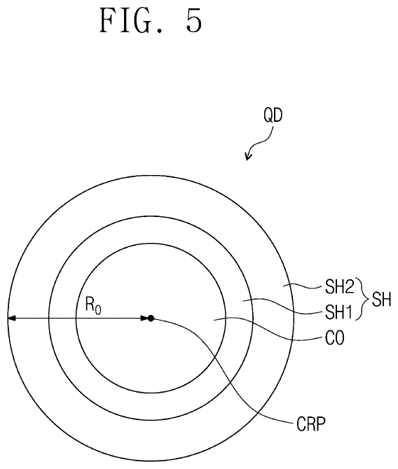

The physical or chemical properties such as structures and materials of the quantum dots QD1, QD2, and QD3 according to an embodiment will be described in detail with reference to FIG. 5 below.

In the light-emitting element ED according to an embodiment, the electron transport region ETR may be provided on the light-emitting layers EML-B, EML-G, and EML-R. The electron transport region ETR may include at least one of an electron transport layer (not shown) or an electron injection layer (not shown), but embodiments are not limited thereto.

The electron transport region ETR may be a layer consisting of a single material, a layer including different materials, or a structure including multiple layers including different materials. For example, the electron transport region ETR may have a structure consisting of a single layer such as an electron injection layer or an electron transport layer, or may have a structure including an electron injection material and an electron transport material. The electron transport region ETR may have a thickness in a range of, for example, about 20 nm to about 150 nm.

The electron transport region ETR may be formed through various methods such as a vacuum evaporation method, a spin coating method, a cast method, a Langmuir-Blodgett (LB) method, an inkjet printing method, a laser printing method, or a laser induced thermal imaging (LITI) method.

The electron transport region ETR may include, for example, anthracene-based compounds, Alq₃(tris(8-hydroxyquinolinato)aluminum), 1,3,5-tri[(3-pyridyl)-phen-3-yl]benzene, 2,4,6-tris(3′-(pyridin-3-yl)biphenyl-3-yl)-1,3,5-triazine, bis[2-(diphenylphosphino)phenyl]ether oxide (DPEPO), 2-(4-(N-phenylbenzoimidazolyl-1-ylphenyl)-9,10-dinaphthylanthracene, 1,3,5-tri(1-phenyl-1H-benzo[d]imidazol-2-yl)phenyl (TPBi) or a mixture thereof. In another embodiment, the electron transport region ETR may include a metal halide such as LiF, NaCl, CsF, RbCl, or RbI, a lanthanide metal such as Yb, a metal oxide such as Li₂O, BaO, or lithium quinolate (LiQ).

The second electrode EL2 may be provided on the electron transport region ETR. The second electrode EL2 may be a common electrode or a cathode. The second electrode EL2 may be a transmissive electrode, a transflective electrode, or a reflective electrode. When the second electrode EL2 is a transmissive electrode, the second electrode EL2 may be formed of a transparent metal oxide, for example, indium tin oxide (ITO), indium zinc oxide (IZO), zinc oxide (ZnO), or indium tin zinc oxide (ITZO). When the second electrode EL2 is a transflective electrode or a reflective electrode, the second electrode EL2 may include Ag, Mg, Cu, Al, Pt, Pd, Au, Ni, Nd, Jr, Cr, Li, Ca, LiF/Ca, LiF/Al, Mo, Ti, Yb, W, a compound thereof, or a mixture thereof. In another embodiment, the second electrode EL2 may have a multilayer structure including a reflective film or a semi-transmissive film formed of the materials described above, and a transparent conductive film formed of indium tin oxide (ITO), indium zinc oxide (IZO), zinc oxide (ZnO), or indium tin zinc oxide (ITZO).

Although not illustrated, the second electrode EL2 may be electrically connected to an auxiliary electrode. When the second electrode EL2 is electrically connected to an auxiliary electrode, the resistance of the second electrode EL2 may be reduced. The light-emitting elements ED-1, ED-2, and ED-3 may emit light of different wavelength ranges. For example, in an embodiment, the display device DD may include the first light-emitting element ED-1 emitting blue light, the second light-emitting element ED-2 emitting green light, and the third light-emitting element ED-3 emitting red light. The blue light-emitting region PXA-B, the green light-emitting region PXA-G, and the red light-emitting region PXA-R of the display device DD may respectively correspond to the first light-emitting element ED-1, the second light-emitting element ED-2, and the third light-emitting element ED-3. However, embodiments are not limited thereto, and the first to third light-emitting elements ED-1, ED-2, and ED-3 may emit light of a same wavelength range or at least one of the first to third light-emitting elements ED-1, ED-2, and ED-3 may emit light of a different wavelength range.

Referring to FIGS. 3 and 4A, the areas of the respective light-emitting regions PXA-B, PXA-G, and PXA-R in the display device DD according to an embodiment may be different from each other. For example, the light-emitting regions PXA-B, PXA-G, and PXA-R may have different areas according to the colors of light emitted from the light-emitting layer EML-B, EML-G, and EML-R of the light-emitting elements ED-1, ED-2, and ED-3. Each of the areas may be an area in a plan view defined by the first direction DR1 and the second direction DR2. For example, in the display device DD according to an embodiment, the blue light-emitting region PXA-B corresponding to the first light-emitting element ED-1 emitting blue light may have the largest area in a plan view, and the green light-emitting region PXA-G corresponding to the second light-emitting element ED-2 generating green light may have the smallest area in a plan view. However, embodiments are not limited thereto. The light-emitting regions PXA-B, PXA-G, and PXA-R may emit light of colors other than red light, green light, and blue light. The light-emitting regions PXA-B, PXA-G, and PXA-R may have a same area, or may have areas which are different from those illustrated in FIG. 3.

FIG. 4A illustrates that in the display device DD according to an embodiment, a thicknesses of the light-emitting layers EML-B, EML-G, and EML-R of the first to third light-emitting elements ED-1, ED-2, and ED-3 may all be similar, but embodiments are not limited thereto. For example, in an embodiment, the thicknesses of the light-emitting layers EML-B, EML-G, and EML-R of the first to third light-emitting elements ED-1, ED-2, and ED-3 may be different from each other.

Referring to FIG. 4B, the display element layer DP-EL1 may include the light-emitting element ED-a disposed on the pixel defining film PDL. The display element layer DP-EL1 may include the light-emitting element ED-a. The light-emitting element ED-a may include the first electrode EL1 and the second electrode EL2 which face each other, and layers OL disposed between the first electrode EL1 and the second electrode EL2. As illustrated in FIG. 4A, the layers OL may include a hole transport region, a light-emitting layer, and an electron transport region. Although not illustrated in the drawings, in an embodiment, the layers OL may have a structure in which multiple layers OL are stacked. For example, a stack of the layers OL may include a hole transport region, a light-emitting layer, and an electron transport region, and another stack of the layers OL may have a structure in which three or more of the layers OL are stacked.

In the light-emitting element ED-a according to an embodiment, the light-emitting layer may include a host and a dopant, which may be organic electroluminescent materials, or may include a quantum dot according to the above-described embodiment. In the display panel DP-1 according to an embodiment, the light-emitting element ED-a may emit blue light having a central wavelength of in a range of about 420 nm to about 480 nm. Although not illustrated in the drawings, in an embodiment a capping layer may be further disposed on the second electrode EL2.

Referring to FIGS. 4A and 4B, the encapsulation layer TFE may be disposed on the light-emitting elements ED-1, ED-2, ED-3, and ED-a, and may cover the light-emitting elements ED-1, ED-2, ED-3, and ED-a. The encapsulation layer TFE may be a single layer or a stack of multiple layers. The encapsulation layer TFE may be a thin-film encapsulation layer. The encapsulation layer TFE protects the light-emitting elements ED-1, ED-2, ED-3, and ED-a. The encapsulation layer TFE may cover an upper surface of the second electrode EL2 disposed in the opening OH and may fill the opening OH.

Referring to FIGS. 4A and 4B, display devices DD and DD-1 according to an embodiment may respectively include optical structure layers PP and PP-1. The optical structure layers PP and PP-1 may block external light provided to the display panels DP and DP-1 from the outside of the display devices DD and DD-1. The optical structure layers PP and PP-1 may block a portion of the external light. The optical structure layers PP and PP-1 may have an anti-reflection function to minimize reflection of the external light.

Referring to FIG. 4B, the display device DD-1 according to an embodiment may include a light control layer CCL disposed on the display panel DP-1.

The light control layer CCL may include a light converter. The light converter may be a quantum dot or a phosphor. The light converter may convert the wavelength of a provided light and emit the converted light. For example, the light control layer CCL may be a layer including quantum dots or a layer including phosphors.

The light control layer CCL may include multiple partition wall portions BK spaced apart from each other and light control parts CCP-R, CCP-B, and CCP-G disposed between the partition wall portions BK. The partition wall portion BK may be formed of a polymer resin and a liquid repellent additive. The partition wall portion BK may include a light-absorbing material or may include a pigment or a dye. For example, the partition wall portion BK may be formed by including a black pigment or black dye to form a black partition wall portion. Carbon black or the like may be used as the black pigment or black dye when the black partition wall portion is formed, but embodiments are not limited thereto.

The light control layer CCL may include a first light control part CCP-B that transmits a source light emitted from the light-emitting element ED-a, a second light control part CCP-G including a fourth quantum dot QD2-a that converts the source light into a first light, and a fifth quantum dot QD3-a that converts the source light into a second light. The first light may have a longer wavelength region than the source light, and the second light may have a longer wavelength region than the source light and the first light. For example, the source light may be blue light, the first light may be green light, and the second light may be red light. For example, the fourth quantum dot QD2-a may be a green quantum dot, and the fifth quantum dot QD3-a may be a red quantum dot.

The light control layer CCL may further include a scatterer. The first light control part CCP-B may include no quantum dot and may include the scatterer. The second light control part CCP-G may include the fourth quantum dot QD2-a and the scatterer, and the third light control part CCP-R may include the fifth quantum dot QD3-a and the scatterer.

Each of the first light control part CCP-B, the second light control part CCP-G, and the third light control part CCP-G may include a base resin for dispersing the quantum dots and the scatterers. In an embodiment, the first light control part CCP-B may include the scatterer dispersed in the base resin, the second light control part CCP-G may include the fourth quantum dot QD2-a and the scatterer dispersed in the base resin, and the third light control part CCP-R may include the fifth quantum dot QD3-a and the scatterer dispersed in the base resin.

The light control layer CCL may further include a capping layer CPL. The capping layer CPL may be disposed under the light control parts CCP-B, CCP-G, and CCP-R and the partition wall portion BK. The capping layer CPL may function to prevent permeation of moisture and/or oxygen (hereinafter, referred to as moisture/oxygen). The capping layer CPL may be disposed on the light control parts CCP-B, CCP-G, and CCP-R and may block the light control parts CCP-B, CCP-G, and CCP-R from being exposed to moisture/oxygen. The capping layer CPL may include at least one inorganic layer.

Referring to FIGS. 4A and 4B, the optical structure layers PP and PP-1 according to an embodiment may each include a base layer BL and a color filter layer CFL.

The base layer BL may provide a base surface on which the color filter layer CFL is disposed. The base layer BL may be a glass substrate, a metal substrate, a plastic substrate, or the like. However, embodiments are not limited thereto, and the base layer BL may include an inorganic layer, an organic layer, or a composite material layer.

The color filter layer CFL may include the color filters CF-B, CF-G, and CF-R. The color filter layer CFL may include a first color filter CF-B that transmits a portion of the source light, a second color filter CF-G that transmits the first light, and a third color filter CF-R that transmits the second light. In another embodiment, the color filter layer CFL may include a first color filter CF-B that transmits blue light, a second color filter CF-G that transmits green light, and a third color filter CF-R that transmits red light. In an embodiment, the first color filter CF-B may be a blue filter, the second color filter CF-G may be a green filter, and the third color filter CF-R may be a red filter.

Each of the color filters CF-B, CF-G, and CF-R may include a polymer photosensitive resin and a colorant. The first color filter CF-B may contain a blue colorant, the second color filter CF-G may contain a green colorant, and the third color filter CF-R may contain a red colorant. The first color filter CF-B may include a blue pigment or blue dye, the second color filter CF-R may include a green pigment or green dye, and the third color filter CF-R may include a red pigment or red dye.

The first to third color filters CF-B, CF-G, and CF-R may be disposed to respectively correspond to the first pixel region PXA-B, the second pixel region PXA-G, and the third pixel region PXA-R. The first to third color filters CF-B, CF-G, and CF-R may be disposed to respectively correspond to the first to third light control parts CCP-R, CCP-B, and CCP-G.

The color filters CF-B, CF-G, and CF-R that transmit different light may be disposed corresponding to the peripheral region NPXA disposed between the pixel regions PXA-R, PXA-B, and PXA-G such that the color filters CF-B, CF-G, and CF-R overlap each other. The color filters CF-B, CF-G, and CF-R may be disposed to overlap each other in the third direction DR3, which may be the thickness direction, so that adjacent light-emitting regions PXA-R, PXA-B, and PXA-G may be distinguished. Accordingly, the light-blocking effect of external light may be increased, and thus, the same function as a black matrix may be obtained. An overlapping structure of the color filters CF-B, CF-G, and CF-R may have a function of preventing color mixing.

Although not illustrated in the drawings, the color filter layer CFL may include light blocking parts (not shown) for distinguishing boundaries between the adjacent color filters CF-B, CF-G, and CF-R. The light blocking parts (not shown) may include a blue filter or may include an organic light blocking material or an inorganic light blocking material that contains a black pigment or a black dye.

However, embodiments are not limited thereto, and the first color filter CF-B may include no pigment or dye. The first color filter CF-B may include a polymer photosensitive resin but may include no pigment or dye. The first color filter CF-B may be transparent. The first color filter CF-B may be formed of a transparent photosensitive resin.

The color filter layer CFL may further include a buffer layer BFL. For example, the buffer layer BFL may be a protective layer that protects the color filters CF-B, CF-G, and CF-R. The buffer layer BFL may be an inorganic material layer including at least one inorganic material selected from silicon nitride, silicon oxide, and silicon oxynitride. The buffer layer BFL may be formed of a single layer or multiple layers.

Although not illustrated in FIGS. 4A and 4B, in an embodiment, the optical structure layer PP of the display device DD may not include the color filter layer CFL. For example, the optical structure layer PP of the display device DD according to an embodiment may include only the base layer BL or may include only the base layer BL and the light control layer CCL.

Although not illustrated in FIGS. 4A and 4B, in an embodiment, the optical structure layer PP of the display device DD may include a polarization layer (not shown) in place of the color filter layer CFL. The polarization layer (not shown) may block external light provided to the display panel DP from the outside. The polarization layer may block a portion of the external light. The polarization layer may reduce reflected light generated from reflection of the external light at the display panel DP. For example, the polarization layer (not shown) may block reflected light when light provided from the outside of the display device DD enters the display panel DP and is emitted again.

FIG. 5 is a schematic cross-sectional view of a structure of a quantum dot QD according to an embodiment. At least one of the first to third quantum dots QD1, QD2, and QD3 described in FIG. 4A may be the quantum dot QD according to an embodiment illustrated in FIG. 5. For example, the second quantum dot QD2 may be the quantum dot QD of FIG. 5. At least one of the quantum dots QD2-a and QD3-a respectively included in the light control parts CCP-G and CCP-R described in FIG. 4B may be the quantum dot QD according to an embodiment illustrated in FIG. 5. For example, the fourth quantum dot QD2-a that converts the first light into the second light may be the quantum dot QD of FIG. 5.

Referring to FIG. 5, the quantum dot may include a core CO and a shell SH surrounding the core CO.

The core CO may include zinc (Zn), tin (Sn), and phosphorus (P). The core CO may include a Group II-IV-V semiconductor compound. The core CO may include a Group II-IV-V compound of ZnSnP₂. The core CO may consist of zinc, tin, and phosphorus. A molar ratio of a number of moles of zinc to a number of moles of tin in the core CO may be in a range of about 0.1 to about 2. For example, the molar ratio of the number of moles of zinc to the number of moles of tin in the core CO may be in a range of about 0.3 to about 1.5. The quantum dot QD according to an embodiment may have a high blue light absorption rate by including the Group II-IV-V semiconductor compound of ZnSnP₂ in the core CO and by adjusting the molar ratios of zinc and tin to the above range.

The core CO according to an embodiment may have an absorption wavelength in a range of about 350 nm to about 530 nm. The core CO may emit green light or red light by absorbing blue light in the above-described wavelength range. The quantum dot QD according to an embodiment may have a weight absorption coefficient in a range of about 350 mL·g⁻¹·cm⁻¹ to about 1000 mL·g⁻¹·cm⁻¹ with respect to a wavelength of about 450 nm. For example, the quantum dot QD according to an embodiment may have a weight absorption coefficient in a range of about 500 mL·g⁻¹·cm⁻¹ to about 1000 mL·g⁻¹·cm⁻¹ with respect to a wavelength of about 450 nm. Accordingly, the quantum dot QD according to an embodiment may absorb a large amount of high-purity blue light in a central wavelength in a range of about 440 nm to about 465 nm.

As the core CO includes zinc, tin, and phosphorus, and the molar ratio of the number of moles of zinc to the number of moles of tin is in a range of about 0.1 to about 2, the quantum dot QD according to an embodiment may have high luminous efficiency and high color purity. For example, the quantum dot QD according to an embodiment may absorb a large amount of blue light by including the molar ratios of the elements included in the core CO within the above-described range, thereby emitting green or red light with high color purity. For example, the quantum dot QD according to an embodiment absorbs a large amount of blue light having a central wavelength in a range of about 350 nm to about 530 nm, so that the emission color purity of green light having a central wavelength in a range of about 480 nm to about 560 nm may be increased. However, embodiments are not limited thereto, and the quantum dot QD may absorb or emit light having a wavelength range different from the above-described range, and the emission wavelength of light emitted from the quantum dots QD may be adjusted according to the size of the core CO and the thickness of the shell SH, etc.

The core may include zinc, tin, and phosphorus, and may further include at least one of a Group II element (excluding zinc), a Group IV element (excluding tin), or a Group V element (excluding phosphorus). A molar ratio of a number of moles of the Group II element (excluding zinc) to a number of moles of zinc may be in a range of about 0.1 to about 1, a molar ratio of the number of moles of the Group IV element (excluding tin) to a number of moles of tin may be in a range of about 0.1 to about 1, and a molar ratio of a number of moles of the Group V element (excluding phosphorus) to a number of moles of phosphorus may be in a range of about 0.1 to about 1. For example, the core CO may further include cadmium (Cd) or mercury (Hg), which is a Group II element. For example, the core CO may further include any one of Group IV elements such as silicon (Si), germanium (Ge), or lead (Pb). For example, the core CO may further include any one of Group V elements such as arsenic (As), antimony (Sb), and bismuth (Bi). However, embodiments are not limited thereto.

In an embodiment, the quantum dot QD may not include a Group I element, a Group III element, or a Group VI element. For example, in an embodiment, the quantum dot QD may be a non-In-based quantum dot. For example, the quantum dot QD may not include indium (In).

The shell SH may include a first shell SH1 surrounding the core CO, and a second shell SH2 surrounding the first shell SH1.

The shell SH may include at least one of a Group II-VI compound, a Group III-V compound, a Group III-VI compound, a Group I-III-VI compound, a Group II-V compound, a Group II-IV-V compound, a Group IV-V compound, or any combination thereof.

The Group II-VI compound included in the shell SH may include: a binary compound selected from the group consisting of CdSe, CdTe, CdS, ZnS, ZnSe, ZnTe, ZnO, HgS, HgSe, HgTe, MgSe, MgS and a mixture thereof; a ternary compound selected from the group consisting of CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, MgZnS and a mixture thereof; and a quaternary compound selected from the group consisting of HgZnTeS, CdZnSeS, CdZnSeTe, CdZnSTe, CdHgSeS, CdHgSeTe, CdHgSTe, HgZnSeS, HgZnSeTe, HgZnSTe and a mixture thereof. However, embodiments are not limited thereto.

The Group III-V compound included in the shell SH may include: a binary compound selected from the group consisting of GaN, GaP, GaAs, GaSb, AlN, AlP, AlAs, AlSb, InN, InP, InAs, InSb, and a mixture thereof; a ternary compound selected from the group consisting of GaNP, GaNAs, GaNSb, GaPAs, GaPSb, AlNP, AINAs, AlNSb, AlPAs, AlPSb, InGaP, InAlP, InNP, InNAs, InNSb, InPAs, InPSb and a mixture thereof; and a quaternary compound selected from the group consisting of GaAlNP, GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, InAlPSb and a mixture thereof. However, embodiments are not limited thereto.

The Group III-VI compound included in the shell SH may include: a binary compound such as In 2 S 3 and In 2 Se 3; a ternary compound such as InGaS₃ and InGaSe₃; or any combination thereof. However, embodiments are not limited thereto.

The Group I-III-VI compound included in the shell SH may include: a ternary compound selected from the group consisting of AgInS, AgInS₂, CuInS, CuInS₂, AgGaS₂, CuGaS₂ CuGaO₂, AgGaO₂, AgAlO₂ and a mixture thereof; or a quaternary compound such as AgInGaS₂ or CuInGaS₂. However, embodiments are not limited thereto.

The Group II-V compound included in the shell SH may include: a ternary compound selected from the group consisting of: Cd₃PN, Cd₃PAs, Cd₃AsN, Cd₂ZnP₂, Cd₂ZnAs₂, Cd₂ZnN₂ and a mixture thereof; or a quaternary compound such as CdZnPN, CdZnPAs, or Cd₂ZnAsN. However, embodiments are not limited thereto.

The Group II-IV-V compound included in the shell SH may include a ternary compound selected from the group consisting of ZnSiAs₂, CdGeAs₂ and a mixture thereof. However, embodiments are not limited thereto.

The Group IV-V compound included in the shell SH may include a secondary compound selected from the group consisting of SiP, SiAs, GeP, GeAs, SnP, and a mixture thereof. However, embodiments are not limited thereto.

For example, the first shell SH1 or the second shell SH2 may each independently include at least one of ZnSe, ZnS, ZnTe, ZnO, ZnMg, ZnMgSe, ZnMgS, ZnMgAl, GaSe, GaTe, GaP, GaAs, GaSb, InAs, InSb, AlP, AlAs, AlSb, MnS, MnSe, MgS, or MgSe. In an embodiment, the first shell SH1 or the second shell SH2 may each independently include at least one of ZnSe, ZnS, ZnSeS, GaS, or InSe. For example, the first shell SH1 and the second shell SH2 may each independently include any one of ZnSe, ZnSeS, or ZnS.

The first shell SH1 may entirely surround the core CO, and the second shell SH2 may entirely surround the first shell SH1. Accordingly, the surface of the quantum dot QD may be defined by an outer surface of the second shell SH2. The first shell SH1 may be covered by the second shell SH2 and may not be exposed to the outside of the quantum dot QD. As the quantum dot QD according to an embodiment includes the first shell SH1 and the second shell SH2, the passivation effect on the core CO may be excellent. Accordingly, the quantum dot QD according to an embodiment may exhibit high quantum yield characteristics.

The second shell SH2 may have a single-layer or multi-layered structure. For example, the second shell SH2 may be a layer consisting of a single material, a layer including different materials, or a structure including multiple layers including different materials. When the second shell SH2 has a multilayer structure, the compositions of different layers may be different from each other. The compositions of the layers may change discontinuously within the second shell SH2 or may continuously change within the second shell SH2.

The quantum dot QD according to an embodiment may have a narrow full width at half maximum (FWHM) by including the second shell SH2 surrounding the first shell SH1, and thus both the quantum yield and the quantum yield maintenance rate may be improved. According to embodiments, since the quantum dot QD includes the second shell SH2 surrounding the first shell SH1, excellent chemical stability may be exhibited and the quantum yield may be improved.

In an embodiment, the quantum dot QD may include a central portion CRP. The radius R₀ of the quantum dot QD may be defined as a distance from the central portion CRP to the surface of the quantum dot QD. The quantum dot QD may have a radius R₀ in a range of about 0.5 nm to about 5 nm. For example, the quantum dot QD may have a radius R₀ in a range of about 2 nm to about 3 nm. When the quantum dot QD satisfies any of the ranges of the radius R₀ as described above, the quantum dot QD may not only exhibit a characteristic behavior as a quantum dot QD but may also have excellent dispersibility. Since the average particle diameter of the quantum dot QD may be variously selected within the range as described above, the emission wavelength of the quantum dot QD and/or the semiconductor properties of the quantum dot may be variously changed.

When the quantum dot QD satisfies any of the ranges of the radius R₀ as described above, the quantum dot QD may emit green light. The quantum dot QD may emit light having a central wavelength in a range of about 480 nm to about 560 nm. For example, the quantum dot QD may emit light having a maximum emission wavelength in a range of about 510 nm about 540 nm. However, embodiments are not limited thereto, and the quantum dot QD may emit red light. For example, the quantum dot QD may emit light having a maximum emission wavelength in a range of about 630 nm to about 680 nm.

The shape of the quantum dot QD is not limited to shapes of the related art. For example, the quantum dot may have a spherical shape, a pyramidal shape, a multi-arm shape, or a cubic shape, or the quantum dot may be in the form of a nanoparticle, a nanotube, a nanowire, a nanofiber, or a nanoplatelet particle. In an embodiment, the quantum dot QD may have a spherical shape.

In an embodiment, the quantum dot QD may have a full width at half maximum (FWHM) of an emission wavelength spectrum equal to or less than about 50 nm. For example, the quantum dot QD may have a FWHM of an emission wavelength spectrum equal to or less than about 40 nm. When the FWHM of the quantum dot QD satisfies any of the above-described ranges, the color purity and color reproducibility of the quantum dot QD may be improved. Light emitted through such a quantum dot QD may be emitted in all directions, so that wide viewing angle characteristics may be improved.

Although not illustrated, the quantum dot QD may further include a ligand chemically bonded to the surface thereof. The ligand may be chemically bonded to the surface of the quantum dot QD to passivate the quantum dot QD. For example, the quantum dot QD may further include a ligand chemically bonded to the second shell SH2. In an embodiment, the ligand may include an organic ligand or a metal halide.

Hereinafter, a method for preparing a quantum dot according to an embodiment will be described with reference to the accompanying drawings. In describing the method for preparing a quantum dot according to an embodiment, a detailed description of a same configuration as the above-described configuration may be omitted.

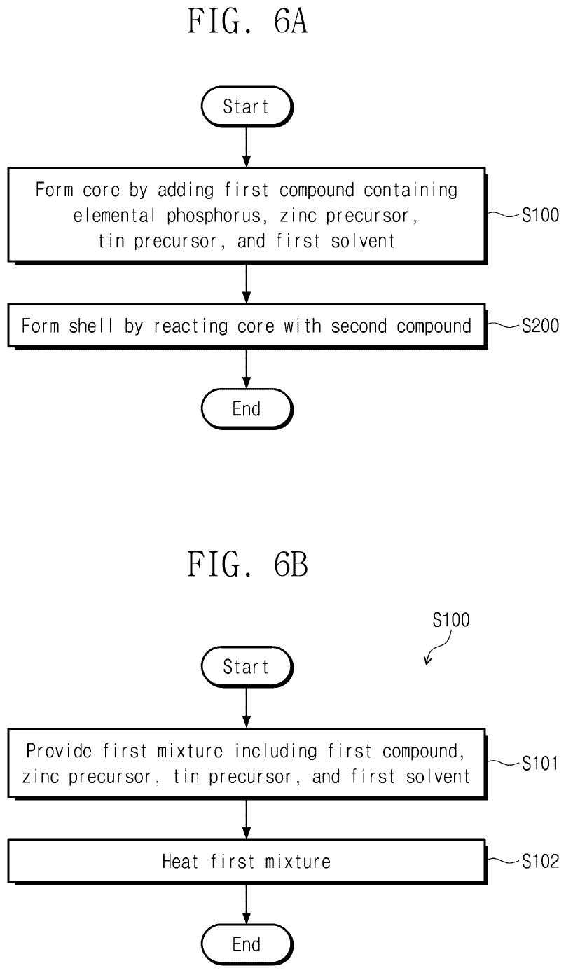

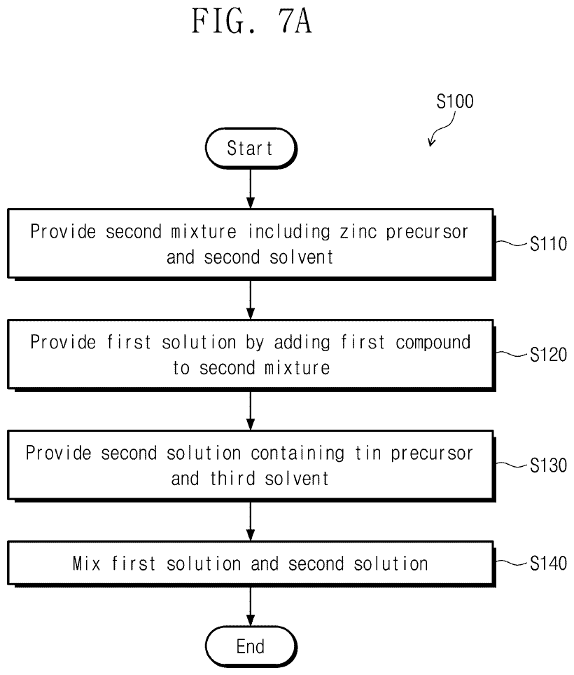

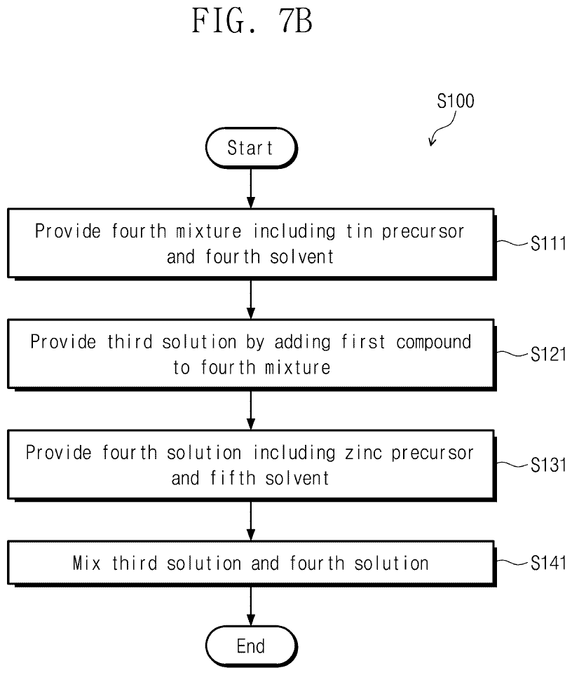

FIGS. 6A and 6B are flowcharts illustrating a method for preparing a quantum dot according to an embodiment. FIGS. 7A and 7B are flowcharts illustrating forming a core in a method for preparing a quantum dot according to an embodiment.

Referring to FIG. 6A, a method for preparing a quantum dot according to an embodiment may include forming a core containing elemental zinc, elemental tin, and elemental phosphorus by adding an elemental phosphorus-containing first compound, a zinc precursor, and a tin precursor (S100), and forming a shell by reacting the core with a second compound (S200).

Referring to FIG. 6B, the forming of the core (S100) may include providing a first mixture including the elemental phosphorus-containing first compound, the zinc precursor, the tin precursor, and a first solvent (S101). The providing of the first mixture (S101) may include mixing a first compound containing the elemental phosphorus, the zinc precursor, and the tin precursor. The providing of the first mixture (S101) may include dispersing the elemental phosphorus-containing first compound, the zinc precursor, and the tin precursor in the first solvent. The first solvent may be a material that coordinates the surface of the core to be prepared later and improves the dispersibility of the core. The first solvent may affect the light emission and electrical properties of the prepared quantum dot QD. The providing of the first mixture (S101) may include providing a first preliminary mixture containing the zinc precursor, the tin precursor, and the first solvent, and adding the elemental phosphorus-containing first compound into the first preliminary mixture. The first preliminary mixture may further contain a ligand. The method may further include removing oxygen and moisture in the first preliminary mixture while degassing and stirring the first preliminary mixture at a temperature in a range of 80° C. to about 120° C. for about 30 minutes after the providing of the first preliminary mixture. The adding of the first compound to the first preliminary mixture may be performed at a temperature in a range of 50° C. to about 100° C.

In the method for preparing the quantum dot according to an embodiment, the forming of the core (S100) may further include heating the first mixture to a temperature in a range of about 100° C. to about 300° C. (S102) after the providing of the first mixture (S101). For example, the forming of the core (S100) may include mixing and stirring the elemental phosphorus-containing first compound, the zinc precursor, the tin precursor, and the first solvent to form a first mixture and heating the first mixture at a temperature in a range of about 100° C. to about 300° C.

Referring to FIGS. 7A and 7B, the forming of the core (S100) may include an exchange reaction of zinc cations of the zinc precursor and tin cations of the tin precursor.

Referring to FIG. 7A, the forming of the core (S100) may include providing a second mixture including the zinc precursor and a second solvent (S110), providing a first solution by adding the elemental phosphorus-containing first compound to the second mixture (S120), providing a second solution containing the tin precursor and a third solvent (S130), and mixing the first solution and the second solution (S140). The forming of the core (S100) may include providing the second mixture including the zinc precursor and the second solvent (S110). The second mixture may further include a ligand as needed. The method may further include removing oxygen and moisture in the second mixture while degassing and stirring the second mixture at a temperature in a range of 80° C. to about 120° C. for about 30 minutes after the providing of the second mixture (S110).

The method may include providing the first solution by adding the first compound to the second mixture (S120) after the providing of the second mixture (S110). The first solution may include the second solvent. The providing of the first solution (S120) may include providing a third mixture by adding the first compound to the second mixture and forming a zinc phosphide compound by heating the third mixture. When the third compound is heated, the zinc phosphide compound may be formed. The heating of the third mixture may be performed at a temperature in a range of about 50° C. to about 100° C. For example, the zinc phosphide compound may include a Zn₃P₂ compound.

The method may include providing the second solution including the tin precursor and the third solvent (S130) after the providing of the first solution (S120). The second solution may further contain a ligand as needed. The providing of the second solution (S130) may be performed in a system separate from that for the third mixture. The method may further include removing oxygen and moisture in the second solution while degassing and stirring the second solution at a temperature in a range of about 80° C. to and about 120° C. for about 30 minutes after the providing of the second solution (S130).

The method may include mixing the first solution and the second solution (S140) after the providing of the second solution (S130). The mixing of the first solution and the second solution (S140) may include an exchange reaction between zinc cations of the first solution and tin cations of the second solution. The mixing of the first solution and the second solution (S140) may include an exchange reaction between zinc cations of the zinc precursor and tin cations of the tin precursor.

The mixing of the first solution and the second solution (S140) may include adding a second solution to the first solution or adding the first solution to the second solution. The mixing of the first solution and the second solution (S140) may be performed at a temperature in a range of about 50° C. to about 300° C. Although not illustrated, the method may include heating the above mixture to a temperature in a range of about 100° C. to about 300° C. after the mixing of the first solution and the second solution (S140).

Referring to FIG. 7B, the forming of the core (S100) may include providing a fourth mixture containing the tin precursor and a fourth solvent (S111), providing a third solution by adding the first compound containing elemental phosphorus to the fourth mixture (S121), providing a fourth solution containing the zinc precursor and a fifth solvent (S131), and mixing the third solution and the fourth solution (S141). The forming of the core (S100) may include providing the fourth mixture containing the tin precursor and the fourth solvent (S111). The fourth mixture may further include a ligand as needed. The method may further include removing oxygen and moisture in the fifth mixture while degassing and stirring the fifth mixture at a temperature in a range of about 80° C. to about 120° C. for about 30 minutes after the providing of the fourth mixture (S111).

The method may further include providing the third solution by adding the first compound to the fourth mixture (S121) after the providing of the fourth mixture (S111). The providing of the third solution (S121) may include providing a fifth mixture by adding the first compound to the fourth mixture, and forming a tin phosphide compound by heating the fifth mixture. When the fifth compound is heated, a tin phosphide compound may be formed. The heating of the fifth mixture may be performed at a temperature in a range of about 50° C. to about 100° C. For example, the tin phosphide compound may include a Sn₃P₄ compound.

The method may include providing the fourth solution containing the zinc precursor and a fifth solvent (S131) after the providing of the third solution (S121). The fourth solution may further contain a ligand as needed. The providing of the fourth solution (S131) may be performed in a system separate from that for the third solution. The method may further include removing oxygen and moisture in the fourth solution while degassing and stirring at a temperature in a range of about 80° C. to about 120° C. for about 30 minutes after the providing of the fourth solution (S131).

The method may include mixing the third solution and the fourth solution (S141) after the providing of the fourth solution (S131). The mixing of the third solution and the fourth solution may include an exchange reaction between the tin precursor of the third solution and the zinc precursor of the fourth solution. The mixing of the third solution and the fourth solution may include an exchange reaction of zinc cations of the zinc precursor and tin cations of the tin precursor.

The mixing of the third solution and the fourth solution (S141) may include adding the fourth solution to the third solution, or adding the third solution to the fourth solution. The mixing of the third solution and the fourth solution (S141) may be performed at a temperature in a range of about 50° C. to about 300° C. Although not illustrated, the method may include heating the above mixture to a temperature in a range of about 100° C. to about 300° C. after the mixing of the third solution and the fourth solution (S141).

The zinc precursor may include Zn metal powder, ZnO, an alkylated Zn compound (e.g., dialkylzinc of C2 to C30 such as diethylzinc), Zn alkoxide (e.g., zinc ethoxide), Zn carboxylate (e.g., zinc acetate), Zn nitrate, Zn percolate, Zn sulfate, Zn acetylacetonate, Zn halide (e.g., zinc chloride, etc.), Zn cyanide, Zn hydroxide, zinc carbonate, zinc peroxide or any combination thereof. Examples of the zinc precursors may include dimethyl zinc, diethyl zinc, zinc acetate, zinc acetylacetonate, zinc iodide, zinc bromide, zinc chloride, zinc fluoride, zinc carbonate, zinc cyanide, zinc nitrate, zinc oxide, zinc peroxide, zinc perchlorate, zinc sulfate, and any combination thereof. However, embodiments are not limited thereto.

The tin precursor may include a tin ion, or a tin halide compound including tin chloride (II or IV), a hydrate of a tin halide compound, a tin alkoxide compound including tin isopropoxide ([Sn(OR)₂]ₙ), tin acetate (Sn(CH₃CO₂)₂), tin sulfate (SnSO₄), tin 2-ethylhexanoate (Sn(Oct)₂), and any combination thereof. However, embodiments are not limited thereto.

The first compound may include a phosphorus precursor, and the phosphorus precursor may include phosphoric acid containing a phosphate anion (PO₄⁻), and a phosphate such as ammonium phosphate ((NH₄)₃PO₄), hydrogen phosphate (HO₄P⁻²), and dihydrogenphosphate ([H₂PO₄]⁻), and any combination thereof. However, embodiments are not limited thereto.

Any one of the first solvent, the second solvent, the third solvent, the fourth solvent, or the fifth solvent may include oleylamine, octylamine, decylamine, trioctylamine, hexadecylamine, mercaptopropionic acid, dodecanethiol, 1-octanethiol, thionylchloride, trioctylphosphine, trioctylphosphine oxide, hexylphosphonic acid, tetradecylphosphonic acid, octylphosphonic acid or any combination thereof. However, embodiments are not limited thereto.

The method for preparing a quantum dot according to an embodiment may further include purifying the prepared core after the forming of the core (S100). The purifying of the core may be performed using chloroform, ethanol, acetone, or any combination thereof. However, embodiments are not limited thereto, and the purifying of the core in the method for preparing the quantum dot may be omitted depending on process conditions and the like.

The method for preparing a quantum dot according to an embodiment may further include dispersing the core in a sixth solvent after the purifying of the core. The sixth solvent may be an auxiliary solvent added to improve dispersibility of the core. The sixth solvent may include hexane, toluene, chloroform, dimethyl sulfoxide, cyclohexylbenzene, hexadecane, dimethyl formamide, or the like. However, embodiments are not limited thereto.

The core of the quantum dot prepared according to an embodiment includes zinc, tin, and phosphorus, and the molar ratio of zinc to tin in the core may be in a range of about 0.1 to about 2. Accordingly, the prepared quantum dot according to an embodiment may absorb a large amount of high-purity blue light.

After the forming of the core (S100), forming the shell by reacting the core with a second compound (S200) may be performed. The forming of the shell may include adding a second compound including any one of the precursors of a Group II element, a Group III element, a Group IV element, a Group V element, or a Group VI element, to a solution containing the core. After the second compound is added to a solution in which the purified core is dispersed in a solvent, the solution may be reacted and stirred. Accordingly, the core and the precursor may react to form a shell surrounding the core.

The forming of the shell (S200) may include forming the first shell surrounding the core and forming the second shell surrounding the first shell. The forming of the second shell may include adding a second compound including any one of the precursors of a Group II element, a Group III element, a Group IV element, a Group V element, or a Group VI element, to a solution containing a core and a first shell surrounding the core. As described above, after the second compound is added to a solution in which the purified core and the first shell are dispersed in a solvent, the solution may be reacted and stirred. When the second shell has a multilayer structure, the forming of the second shell may be performed two or more times in succession. Any one among the type, content, and reaction temperature conditions of the precursor for forming the multilayer structure of the second shell may be different, but embodiments are not limited thereto.

A Group II precursor may include, for example, one or more selected from the group consisting of dimethyl zinc, diethyl zinc, zinc acetate, zinc acetylacetonate, zinc iodide, zinc bromide, zinc chloride, zinc fluoride, zinc carbonate, zinc cyanide, zinc nitrate, zinc oxide, zinc peroxide, zinc perchlorate, and zinc sulfate. However, embodiments are not limited thereto.

A Group III precursor may include at least one selected from the group consisting of aluminum phosphate, aluminum acetylacetonate, aluminum chloride, aluminum fluoride, aluminum oxide, aluminum nitrate, aluminum sulfate, gallium acetylacetonate, gallium chloride, gallium fluoride, gallium oxide, gallium nitrate, and gallium sulfate. However, embodiments are not limited thereto.

A Group V precursor may include one or more selected from the group consisting of alkyl phosphine, tris(trialkylsilyl)phosphine, tris(dialkylsilyl)phosphine, tris(dialkylamino)phosphine, arsenic oxide, arsenic chloride, arsenic sulfate, arsenic bromide, and arsenic iodide. However, embodiments are not limited thereto. Here, the alkyl phosphine may include at least one of triethyl phosphine, tributyl phosphine, trioctyl phosphine, triphenyl phosphine or tricyclohexyl phosphine.

A Group VI precursor may include any one selected from the group consisting of sulfur, trialkylphosphine sulfide, trialkenylphosphine sulfide, alkylamino sulfide, alkenylamino sulfide, alkyl thiol, selenium, trialkylphosphine selenide, trialkenylphosphine selenide, alkylamino selenide, alkenylamino selenide, trialkylphosphine telluride, trialkenylphosphine telluride, alkylamino telluride, and an alkenylamino telluride. However, embodiments are not limited thereto.

A Group VII precursor may include any one selected from the group consisting of manganese oxide, manganese carbonate, manganese nitrate hydrate, manganese sulfate, and manganese chloride. However, embodiments are not limited thereto.

The method for preparing the quantum dot QD according to an embodiment may further include ashing the prepared quantum dot QD after the forming of the shell. The ashing of the quantum dot QD may include triggering reaction by adding trioctylphosphine. However, embodiments are not limited thereto. A high-purity quantum dot may be prepared by cooling the mixture in which the quantum dot is formed to room temperature, purifying, and redispersing the mixture. The purifying and redispersing may further include separating the quantum dot by adding a non-solvent to the mixture in which the quantum dots are formed. The non-solvent may be a polar solvent that is miscible with the organic solvent used in the reaction but is unable to disperse the quantum dots.

The non-solvent may be determined depending on the organic solvent used in the reaction, and may be one or more selected from the group consisting of acetone, ethanol, butanol, isopropanol, ethanediol, water, tetrahydrofuran, dimethylsulfoxide, diethyl ether, formaldehyde, acetaldehyde, and ethylene glycol. However, embodiments are not limited thereto.

Centrifugation, precipitation, chromatography, or distillation may be used to separate the quantum dot. The separated quantum dot may be washed by being added to a washing solvent as necessary. The washing solvent is not limited, and hexane, heptane, octane, chloroform, toluene, benzene, and the like may be used.

Hereinafter, a quantum dot according to embodiments will be described in detail with reference to the Examples and the Comparative Examples. The following Examples are provided only to assist the understanding of embodiments, and the scope of the disclosure is not limited thereto.

### Examples and Comparative Examples

### Synthesis of Examples 1 to 6

Operation 1: Synthesis of ZnSnP₂ core
Operation 2: Synthesis of ZnSnP₂/ZnS/ZnSe

Zinc acetate, tin acetate, trioctylphosphine oxide (TOPO), oleylamine, trioctylphosphine, and 1-octadecene (1-ODE) as a solvent were put into a three-necked flask and mixed, and the solution was degassed and stirred at 80° C. for 30 minutes to remove oxygen and moisture to thereby form a reaction solution. The reaction solution was cooled to 50° C. in a nitrogen gas atmosphere, a solution in which tris(trimethylsilyl)phosphine and trioctylphosphine were mixed at a ratio (e.g., a predetermined or a selectable ratio) was injected, and the temperature was raised to 100° C. to 300° C. The solution was reacted for a certain period of time, and the core was synthesized by cooling the resultant solution to room temperature to terminate the reaction. The core was purified with acetone and ethanol, and the purified ZnSnP₂ core was redispersed in toluene.

Zinc oleate and trioctylamine as a solvent were mixed in a three-necked flask, and the solution was degassed and stirred at 120° C. for 120 minutes to remove oxygen and moisture to thereby form a reaction solution. ZnSnP₂ core dispersed in toluene, zinc oleate, trioctylphosphine selenide and oleylamine and ZnCl₂ as additives were added to the reaction solution in a nitrogen gas atmosphere, and the solution was reacted at 280° C. for 1 hour to form a zinc selenide (ZnSe) shell.

Zinc oleate, trioctylphosphine sulfide and oleylamine and ZnCl₂ as additives were added to the reaction solution, and the resultant solution was reacted at 320° C. for 1 hour to form a zinc sulfide (ZnS) shell to synthesize a quantum dot having an InP/ZnSe/ZnS structure. The quantum dots were purified with ethanol, and the purified quantum dots were redispersed in toluene.

### Synthesis of Comparative Example 1

Operation 1: Synthesis of the lnP core
Operation 2: Synthesis of lnP/ZnSe/ZnS

Indium acetate, zinc acetate, palmitic acid and 1-octadecene (1-ODE) as a solvent were put into a three-necked flask and mixed, and the solution was degassed and stirred at 120° C. for 120 minutes to remove oxygen and moisture to thereby form a reaction solution. The reaction solution was cooled to 50° C. in a nitrogen gas atmosphere, a solution in which tris(trimethylsilyl)phosphine and trioctylphosphine were mixed at a ratio (e.g., a predetermined or a selectable ratio) was injected, and the temperature was raised to 250° C. to 300° C. The solution was reacted for a certain period of time, and the core was synthesized by cooling the resultant solution to room temperature to terminate the reaction. The core was purified with acetone, and the purified InP core was redispersed in toluene.

Zinc oleate and trioctylamine as a solvent were mixed in a three-necked flask, and the solution was degassed and stirred at 120° C. for 120 minutes to remove oxygen and moisture to thereby form a reaction solution. An InP core dispersed in toluene, zinc oleate, trioctylphosphine selenide and oleylamine and ZnCl₂ as additives were added to the reaction solution in a nitrogen gas atmosphere, and the solution was reacted at 320° C. for 1 hour to form a zinc selenide (ZnSe) shell.

Zinc oleate, trioctylphosphine sulfide and oleylamine and ZnCl₂ as additives were added to the reaction solution, and the resultant solution was reacted at 320° C. for 1 hour to form a zinc sulfide (ZnS) shell to synthesize a quantum dot having an InP/ZnSe/ZnS structure. The quantum dot was purified with ethanol, and the purified quantum dot was redispersed in toluene.

### Synthesis of Comparative Example 2 and 3

Compared to Example 1 to 6, in Comparative Example 2 and 3, a quantum dot having a core as shown in Table 1 below was prepared by changing the addition amount of the zinc precursor and the tin precursor during adding of the zinc precursor and the tin precursor to the first mixture. Except for this, the quantum dot according to Comparative Example 2 and 3 was prepared in the same manner as in Example 1.

TABLE 1

| | Mole of Zinc Atoms In Core(mol)/ |
|---|---|
| | Mole of Tin Atoms In Core (mol) |
| Example 1 | 0.1 |
| Example 2 | 0.3 |
| Example 3 | 0.5 |
| Example 4 | 1 |
| Example 5 | 1.5 |
| Example 6 | 2 |
| Comparative Example 1 | — |
| Comparative Example 2 | 0.05 |
| Comparative Example 3 | 2.5 |

Referring to Table 1, the quantum dot prepared in each of Examples 1 to 6 includes a ZnSnP₂ compound essentially having zinc atoms and tin atoms as a core, and the molar ratio of the number of moles of zinc atoms to the number of moles of tin atoms is in a range of about 0.1 to about 2. Compared to the quantum dots according to Examples 1-6, the quantum dot according to Comparative Example 1 does not contain zinc atoms and tin atoms as a core, but contains an InP compound having indium atoms. The quantum dot prepared in each of Comparative Example 2 and Comparative Example 3 includes a ZnSnP₂ compound essentially having zinc atoms and tin atoms as a core, but the molar ratios of the number of moles of zinc atoms to the number of moles of tin atoms in Comparative Example 2 is less than 0.1 and in Comparative Example 3 is greater than 2.

### Characteristics Evaluation of Examples and Comparative Examples

Table 2 shows the evaluation of the absorbance of the quantum dots at a specific wavelength according to Examples 1 to 6 and Comparative Example 1. For the quantum dot compositions prepared in Examples 1 to 6 and Comparative Example 1, the absorbance (Absorbance units) of a 10 ppm solution was measured with a cuvette having an optical path length of 10 mm using a Cary 300 Bio UV-Vis Spectrophotometer device (manufactured by Agilent Technologies, Inc.), and the weight absorption coefficient (mL·g⁻¹·cm⁻¹) with respect to a wavelength of 450 nm was calculated according to the Lambert-Beer's law. Experimental results are shown in Table 2.

TABLE 2

| | | Weight Absorption |
|---|---|---|
| | Mole of Zinc Atoms (mol)/ | Coefficient (@450 nm) |
| | Mole of Tin Atoms (mol) | (mL · g⁻¹ · cm⁻¹) |
| Example 1 | 0.1 | 352 |
| Example 2 | 0.3 | 724 |
| Example 3 | 0.5 | 820 |
| Example 4 | 1 | 635 |
| Example 5 | 1.5 | 450 |
| Example 6 | 2 | 355 |
| Comparative | — | 230 |
| Example 1 | | |
| Comparative | 0.05 | 122 |
| Example 2 | | |
| Comparative | 2.5 | 160 |
| Example 3 | | |

Referring to Table 2, it may be confirmed that the quantum dots of Examples 1 to 6 show higher light absorption in the wavelength range of blue light than the quantum dots of Comparative Examples 1 to 3. For example, when the molar ratio of the number of moles of zinc atoms to the number of moles of the tin atoms in the quantum dot according to an embodiment is in a range of 0.1 to 2, the weight absorption coefficient with respect to a wavelength of 450 nm is 350 mL·g⁻¹·cm⁻¹ or more. Accordingly, the quantum dot may have high light absorption in the wavelength range of high-purity blue light, and accordingly, green light emission characteristics may be improved. Therefore, the quantum dots of Examples 1 to 6 may exhibit high luminous efficiency and high color purity compared to the quantum dots of Comparative Examples 1 to 3.

The quantum dots of Examples 1 to 6 having the ZnSnP₂ compound show a higher light absorption rate than that of Comparative Example 1 having the InP compound. Quantum dots are materials that exhibit a quantum confinement, and in the case of a quantum dot having a core containing InP, the quantum dot exhibits a stronger quantum confinement effect than the quantum dots having a core containing ZnSnP₂. Accordingly, compared to the quantum dot having a core containing ZnSnP₂, the frequency of transition from the ground state to the excited state is lower than the quantum dot having a core containing InP, and therefore the absorption rate of blue light of the quantum dots decreases, and the overlap region between the emission spectrum and the absorption spectrum widens, thereby resulting in relatively high inter-quantum dot reabsorption. Therefore, the quantum dots of Examples 1 to 6 may exhibit high luminous efficiency and high color purity, high luminous efficiency and color purity for blue light, because inter-quantum dot reabsorption is less than that of Comparative Example 1. According to embodiments, a quantum dot including a core including Zn, Sn, and P and may thus exhibit high luminous efficiency and high color purity. A method for preparing quantum dot according to an embodiment may ensure the chemical stability of the quantum dot by adjusting the precursor composition and reaction temperature, etc., or by performing a cation exchange reaction. Therefore, when the quantum dot according to an embodiment or the quantum dot prepared by the quantum dot preparing method according to an embodiment are applied to the light-emitting layer or the light control layer of the display device, excellent light efficiency and reliability may be ensured.

Embodiments have been disclosed herein, and although terms are employed, they are used and are to be interpreted in a generic and descriptive sense only and not for purposes of limitation. In some instances, as would be apparent by one of ordinary skill in the art, features, characteristics, and/or elements described in connection with an embodiment may be used singly or in combination with features, characteristics, and/or elements described in connection with other embodiments unless otherwise specifically indicated. Accordingly, it will be understood by those of ordinary skill in the art that various changes in form and details may be made without departing from the spirit and scope of the disclosure.

What is claimed is:

1. A quantum dot comprising:
a core including zinc (Zn), tin (Sn) and phosphorus (P); and
a shell surrounding the core, wherein
a molar ratio of a number of moles of zinc to a number of moles of tin is in a range of about 0.1 to about 2.

2. The quantum dot of claim 1, wherein the core further includes at least one of:
a Group II element except zinc;
a Group IV element except tin; or
a Group V element except phosphorus.

3. The quantum dot of claim 2, wherein a molar ratio of a number of moles of the Group II element to the number of moles of zinc, a molar ratio of a number of moles of the Group IV element to the number of moles of tin, and a ratio of a number of moles of the Group V element to a number of moles of phosphorus are each independently in a range of about 0.1 to about 1.

4. The quantum dot of claim 1, wherein the core does not comprise a Group I element, a Group III element, or a Group VI element.

5. The quantum dot of claim 1, wherein the shell comprises at least one of a Group II-VI compound, a Group III-V compound, a Group III-VI compound, a Group I-III-VI compound, a Group II-V compound, a Group II-IV-V compound, or a Group IV-V compound.

6. The quantum dot of claim 1, wherein the shell comprises at least one of ZnSe, ZnS, ZnSeS, GaS, or InS.

7. The quantum dot of claim 1, wherein
the shell comprises:
a first shell surrounding the core; and
a second shell surrounding the first shell, and
each of the first shell and the second shell each independently includes at least one of ZnSe, ZnS, or ZnSeS.

8. The quantum dot of claim 1, wherein the quantum dot has a weight absorption coefficient equal to or greater than about 350 mL·g⁻¹·cm⁻¹ with respect to a wavelength of about 450 nm.

9. The quantum dot of claim 1, wherein
the quantum dot absorbs light having a central wavelength in a range of about 440 nm to about 465 nm, and
the quantum dot emits light having a central wavelength in a range of about 480 nm to about 560 nm.

10. The quantum dot of claim 1, wherein the quantum dot has a radius in a range of about 0.5 nm to about 5 nm.

11. A display device comprising:
a light-emitting element including:
a first electrode;
a light-emitting layer disposed on the first electrode; and
a second electrode disposed on the light-emitting layer; and
a light control layer including:
a first light control part that transmits the source light;
a second light control part that converts the source light into a first light; and
a first quantum dot, wherein
the light-emitting element outputs a source light,
the light control layer is disposed on the light-emitting element,
the first quantum dot includes:
a core containing zinc, tin, and phosphorus;
a shell surrounding the core, and
a molar ratio of a number of moles of zinc to a number of moles of tin is in a range of about 0.1 to about 2.

12. The display device of claim 11, wherein
the first quantum dot absorbs the source light and emits the first light,
the source light has a central wavelength in a range of about 440 nm to about 465 nm, and
the first light has a central wavelength in a range of about 480 nm to about 560 nm.

13. The display device of claim 11, wherein
the light control layer further comprises a third light control part that converts the source light into a second light,
the third light control part includes a second quantum dot,
the second quantum dot absorbs the source light and emits the second light, and
the second light has a central wavelength in a range of about 600 nm to about 640 nm.

14. A method for preparing a quantum dot, the method comprising:
forming a core containing elemental zinc, elemental tin, and elemental phosphorus by adding a first compound containing elemental phosphorus, a zinc precursor, a tin precursor, and a first solvent; and
forming a shell by reacting the core with a second compound, wherein
a molar ratio of a number of moles of zinc to a number of moles of tin in the core is in a range of about 0.1 to about 2.

15. The method of claim 14, wherein the forming of the core comprises:
providing a first mixture including the first compound, the zinc precursor, the tin precursor, and the first solvent; and
heating the first mixture at a temperature in a range of about 100° C. to about 300° C.

16. The method of claim 15, wherein the providing of the first mixture comprises:
providing a first preliminary mixture including the zinc precursor, the tin precursor, and the first solvent; and
adding the first compound to the first preliminary mixture.

17. The method of claim 14, wherein
the forming of the core comprises:
providing a second mixture including the zinc precursor and a second solvent;
providing a first solution by adding the first compound to the second mixture;
providing a second solution containing the tin precursor and a third solvent; and
mixing the first solution and the second solution, and
the mixing of the first solution and the second solution includes an exchange reaction between zinc cations of the first solution and tin cations of the second solution.

18. The method of claim 17, wherein the providing of the first solution comprises:
providing a third mixture by adding the first compound to the second mixture; and
forming a zinc phosphide compound by heating the third mixture.

19. The method of claim 14, wherein
the forming of the core comprises:
providing a fourth mixture containing the tin precursor and a fourth solvent;
providing a third solution by adding the first compound to the fourth mixture;
providing a fourth solution containing the zinc precursor and a fifth solvent; and
mixing the third solution and the fourth solution, and
the mixing of the third solution and the fourth solution includes an exchange reaction between tin cations of the third solution and zinc cations of the fourth solution.

20. The method of claim 19, wherein the providing of the third solution comprises:
providing a fifth mixture by adding the first compound to the fourth mixture; and
forming a tin phosphide compound by heating the fifth mixture.
